(19) United States
(12) Patent Application Publication
(10) Pub. No.: US 2025/0130509 A1
(43) Pub. Date: Apr. 24, 2025

(54) SUBSTRATE PROCESSING METHOD, SUBSTRATE PROCESSING APPARATUS, LITHOGRAPHY APPARATUS, ARTICLE MANUFACTURING METHOD, AND STORAGE MEDIUM

(71) Applicant: CANON KABUSHIKI KAISHA, Tokyo (JP)

(72) Inventors: GENICHIROU KIYOTA, Tochigi (JP); KOICHI TAMURA, Tochigi (JP)

(21) Appl. No.: 18/915,918

(22) Filed: Oct. 15, 2024

(30) Foreign Application Priority Data
Oct. 23, 2023 (JP) 2023-182051

(51) Int. Cl. G03F 7/00

(52) U.S. Cl. CPC G03F 7/70775; G03F 7/70525; G03F 7/7085

(57) ABSTRACT

The present invention provides a substrate processing method of processing a substrate, comprising: measuring a light intensity distribution obtained from a peripheral edge portion of the substrate when the peripheral edge portion is illuminated with light from a light source unit; specifying a plurality of candidates for an edge position of the substrate from the light intensity distribution measured in the measuring, by applying each of a plurality of types of algorithms to the light intensity distribution; and selecting one algorithm used to determine a position of the substrate from the plurality of types of algorithms based on the plurality of candidates specified in the specifying.

### BACKGROUND OF THE INVENTION

### Field of the Invention

The present invention relates to a substrate processing method, a substrate processing apparatus, a lithography apparatus, an article manufacturing method, and a storage medium.

### Description of the Related Art

In a lithography apparatus that forms a pattern on a substrate, before conveying the substrate onto a stage for holding the substrate, processing (so-called prealignment) of detecting the position of the substrate is performed. In the prealignment processing, the edge position of the substrate is detected based on the light intensity distribution obtained from the peripheral edge portion of the substrate when the peripheral edge portion is illuminated with light, and the position (orientation or barycenter position) of the substrate is determined based on the detected edge position of the substrate. With this, it is possible to control positioning of the substrate when conveying the substrate onto the stage.

Japanese Patent Laid-Open No. 2011-181721 describes a method of detecting, using an edge detector including a light source and a line sensor, the edge of a bonded wafer including a wafer support substrate and a semiconductor wafer bonded to the surface of the wafer support substrate. In the method described in Japanese Patent Laid-Open No. 2011-181721, semiconductor wafer edge detection and wafer support substrate edge detection are switched in a predetermined case.

There are several types of substrates that undergo prealignment processing, such as a transparent substrate, an opaque substrate, a substrate obtained by bonding a plurality of members, and the like. If the type of substrate changes, the tendency of the light intensity distribution obtained from the peripheral edge portion of the substrate can change. Hence, in order to accurately detect the position of the substrate even if the type of substrate changes, it is necessary to appropriately select, in accordance with the type of substrate, the algorithm for deciding the position of the substrate from the light intensity distribution. However, performing prealignment processing including a light intensity distribution measurement step a plurality of times while changing the type of algorithm to select the algorithm can be disadvantageous in terms of throughput. That is, prealignment processing is demanded to achieve both the throughput and detection accuracy when detecting the position of the substrate.

### SUMMARY OF THE INVENTION

The present invention provides, for example, a technique advantageous in achieving both the throughput and detection accuracy when detecting the position of a substrate.

According to one aspect of the present invention, there is provided a substrate processing method of processing a substrate, comprising: measuring a light intensity distribution obtained from a peripheral edge portion of the substrate when the peripheral edge portion is illuminated with light from a light source unit; specifying a plurality of candidates for an edge position of the substrate from the light intensity distribution measured in the measuring, by applying each of a plurality of types of algorithms to the light intensity distribution; and selecting one algorithm used to determine a position of the substrate from the plurality of types of algorithms based on the plurality of candidates specified in the specifying.

Further features of the present invention will become apparent from the following description of exemplary embodiments with reference to the attached drawings.

### BRIEF DESCRIPTION OF THE DRAWINGS

FIG. 1 is a schematic view showing an example of the arrangement of a substrate processing apparatus;

FIG. 2 is a view showing an example of detecting the edge position of the substrate;

FIG. 3 is a view showing an example of detecting the edge position of the substrate;

FIG. 4 is a view showing an example of detecting the edge position of the substrate;

FIG. 5 is a view showing an example of detecting the edge position of the substrate;

FIG. 6 is a view showing an example of detecting the edge position of the substrate;

FIGS. 7A and 7B are views showing an example the position waveform representing the outer shape of the substrate and the ideal position waveform;

FIG. 8 is a view for explaining equation (1);

FIG. 9 is a flowchart illustrating the operation sequence of prealignment processing according to the first embodiment;

FIG. 10 is a view for explaining an example of an optimal algorithm selection method;

FIGS. 11A and 11B are views for explaining the example of the optimal algorithm selection method;

FIG. 12 is a view for explaining an example of the optimal algorithm selection method;

FIGS. 13A and 13B are views each showing an example of the position waveform representing the outer shape of the substrate and the ideal position waveform;

FIG. 14 is a flowchart illustrating the operation sequence of prealignment processing according to the second embodiment;

FIG. 15 is a flowchart illustrating the operation sequence of prealignment processing according to the third embodiment;

FIGS. 16A and 16B are views showing an example of the cutout waveform representing the outer shape of the cutout portion of a substrate and the ideal cutout waveform;

FIG. 17 is a flowchart illustrating the operation sequence of prealignment processing according to the fourth embodiment; and

FIG. 18 is a schematic view showing an example of the arrangement of an exposure apparatus.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the holding surface of a substrate chuck 111 (to be described later) used to hold a substrate are defined as the X-Y plane, unless otherwise specified. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and an orientation is information that can be specified by values on the θX-, θY-, and θZ-axes.

### First Embodiment

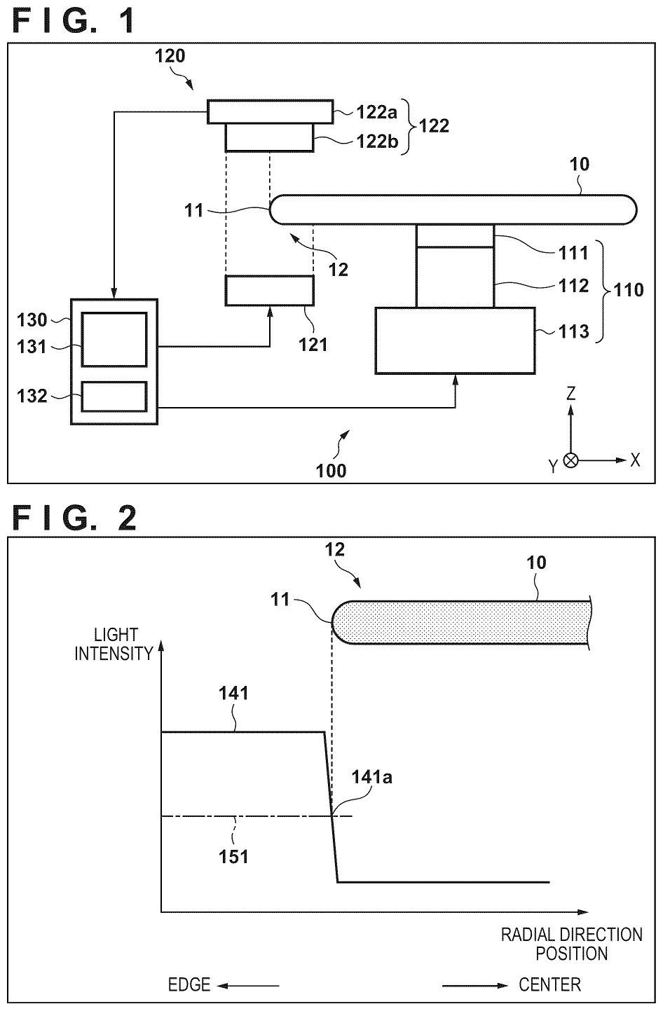

The first embodiment according to the present invention will be described. FIG. 1 is a schematic view showing an example of the arrangement of a substrate processing apparatus 100 of this embodiment. The substrate processing apparatus 100 of this embodiment can include a substrate holder 110, a measurement device 120, and a controller 130.

The substrate processing apparatus 100 of this embodiment is an apparatus that performs processing (so-called prealignment processing) of detecting the position of an edge 11 of a substrate 10 before conveying the substrate 10 onto the substrate stage of a lithography apparatus. In the prealignment processing, the position of the edge 11 of the substrate 10 is detected based on the light intensity distribution obtained from a peripheral edge portion 12 of the substrate 10 when the peripheral edge portion 12 is illuminated with light. By deciding the orientation or center position of the substrate 10 based on the position of the edge 11 of the substrate 10 detected by the prealignment processing, it is possible to control positioning of the substrate 10 when conveying the substrate 10 onto the substrate stage of the lithography apparatus. Note that positioning of the substrate 10 is adjusting (arranging) the substrate 10 to a predetermined position or orientation in terms of a translation direction (for example, X and Y directions) and a rotation direction (for example, θZ direction), and may also be referred to as “alignment of the substrate 10”. The substrate processing apparatus 100 that performs prealignment processing may also be referred to as a “prealignment apparatus”.

The substrate holder 110 is a mechanism for holding and driving the substrate 10, and can include a substrate chuck 111, a rotation driver 112, and a translation driver 113. The substrate chuck 111 uses a vacuum suction force, an electrostatic attraction force, or the like to hold the central portion of the substrate 10 with a holding surface parallel to the X-Y plane. The rotation driver 112 rotationally drives the substrate chuck 111 in the θZ direction with the Z-axis as a rotation axis, thereby rotationally driving the substrate 10 in the θZ direction. The translation driver 113 translationally drives the substrate chuck 111 and the rotation driver 112 in the X and Y directions, thereby translationally driving the substrate 10 in the X and Y directions.

The substrate 10 held by the substrate holder 110 in this embodiment has a cutout portion in the peripheral edge portion 12. The cutout portion of the substrate 10 can be a notch or an orientation flat. Note that the substrate 10 may be a substrate without a cutout portion. Further, the type of the substrate 10 which is held by the substrate holder 110 and undergoes prealignment processing is arbitrary. That is, the substrate processing apparatus 100 of this embodiment can perform prealignment processing on various types of substrates 10 regardless of material, transparency, chamfering, bonding, and the like.

The measurement device 120 is a mechanism for measuring the light intensity distribution obtained from the peripheral edge portion 12 when the peripheral edge portion 12 of the substrate 10 is illuminated with light, and can include a light source unit 121 (light projection unit) and a light receiving unit 122. The light source unit 121 is arranged, for example, on the back surface side (lower side) of the substrate 10, and emits light toward the peripheral edge portion 12 such that the peripheral edge portion 12 of the substrate 10 is arranged only in a part of the optical path. For example, an LED light source can be used as the light source unit 121. The light receiving unit 122 is arranged, for example, on the front surface side (upper side) of the substrate 10 to face the light source unit 121 (light emission surface), and receives light emitted from the light source unit 121. The light receiving unit 122 of this embodiment includes a light receiving element 122a (light receiving sensor) and an optical system 122b. The light receiving element 122a can be an image capturing element such as a CCD image sensor or a CMOS image sensor. The optical system 122b is an imaging optical system configured to form the image of the peripheral edge portion 12 of the substrate 10 on the light receiving surface (image capturing surface) of the light receiving element 122a.

When the substrate 10 is an opaque substrate, of the light emitted from the light source unit 121, the light having passed through the space outside the substrate 10 is received by the light receiving unit 122. On the other hand, when the substrate 10 is a transparent substrate having the chamfered peripheral edge portion 12, of the light emitted from the light source unit 121, the light having passed through the space outside the substrate 10 and the light having passed through the portion of the substrate 10 other than the peripheral edge portion 12 are received by the light receiving unit 122. Note that the space outside the substrate 10 may be understood as the space not shielded by the substrate 10.

Based on, of the light emitted from the light source unit 121, the light received (detected) by the light receiving unit 122, the measurement device 120 measures the light intensity distribution in the radial direction (X direction) obtained from a part of the peripheral edge portion 12 of the substrate 10. While the substrate holder 110 is rotationally driving the substrate 10, the measurement device 120 sequentially measures the light intensity distribution in the radial direction as described above. With this, the light intensity distribution in the radial direction can be obtained for the whole peripheral edge portion 12 of the substrate 10. Note that the light intensity distribution in the radial direction may be simply referred to as the “light intensity distribution” hereinafter.

Here, the measurement device 120 of this embodiment is configured as a transmissive sensor, but the measurement device 120 is not limited to this, and may be configured as a reflective sensor that detects, of the light emitted from the light source unit 121, the light reflected by the peripheral edge portion 12 of the substrate 10 by the light receiving unit 122. The measurement device 120 (light source unit 121) preferably performs bright field illumination. By performing not dark field illumination but bright field illumination, even in a case where the peripheral edge portion 12 of the substrate 10 is chamfered, it can be prevented that the detection accuracy of the position of the edge 11 of the substrate 10 decreases due to the influence of reflected light caused by the chamfering.

The controller 130 can be formed from, for example, a computer (information processing apparatus) including a processor 131 such as a Central Processing Unit (CPU) and a storage unit 132 such as a memory. The controller 130 is connected to respective units of the substrate processing apparatus 100 by lines, thereby controlling the respective units of the substrate processing apparatus 100 (controlling prealignment processing).

In this embodiment, the controller 130 (processor 131) detects the position of the edge 11 of the substrate 10 based on the light intensity distribution measured by the measurement device 120, and controls positioning of the substrate 10 based on the detection result. More specifically, the controller 130 applies each of a plurality of types of algorithms to the light intensity distribution measured by the measurement device 120 to specify a plurality of candidates for the position of the edge 11 of the substrate 10 in the radial direction from the light intensity distribution. Then, based on the plurality of specified candidates, the controller 130 selects one algorithm used to determine the position of the substrate 10 from the plurality of types of algorithms, and determines the position (orientation or barycenter position) of the substrate 10 using the one algorithm. Thus, the controller 130 can accurately position the substrate 10 based on the determined position of the substrate 10. Note that positioning of the substrate 10 may be understood as driving the substrate 10 to arrange the substrate 10 at a predetermined position, that is, to reduce the positional deviation of the substrate 10.

The storage unit 132 stores information necessary for execution of prealignment processing. For example, the storage unit 132 stores a program for executing prealignment processing, and the plurality of types of algorithms used in prealignment processing. Each of the plurality of types of algorithms is set to detect (specify) the position of the edge 11 of the substrate 10 from the light intensity distribution measured by the measurement device 120 for each type of the substrate 10 that may undergo prealignment processing in the substrate processing apparatus 100. The storage unit 132 also stores position information of the edge 11 of the substrate 10 determined by the processor 131, and light intensity distribution measurement conditions (for example, the light amount of the light source unit 121 and the like) in the measurement device 120. Note that the position of the edge 11 of the substrate 10 in the radial direction may be referred to as the “edge position” hereinafter.

### [Detection of Edge Position]

Examples of detecting the edge position of the substrate 10 will be described with reference to FIGS. 2 to 6. Each of FIGS. 2 to 6 shows an example of detecting the edge position of the substrate 10 for each of a plurality of types of substrates 10 different from each other in material and structure. Each of FIGS. 2 to 6 shows the structure of the peripheral edge portion 12 of the substrate 10, and the corresponding light intensity distribution obtained by the light receiving unit 122 of the measurement device 120. The light intensity distribution is shown with the abscissa representing the position of the substrate 10 in the radial direction and the ordinate representing the light receiving intensity (light intensity) in the light receiving unit 122.

FIG. 2 shows an example where the substrate 10 is an opaque substrate (for example, a silicon substrate) and the peripheral edge portion 12 of the substrate 10 is chamfered. In this example, part of the light from the light source unit 121 is blocked by the substrate 10, so that only the light having passed through the space outside the edge 11 of the substrate 10 enters the light receiving unit 122 of the measurement device 120. Accordingly, as shown in FIG. 2, in a light intensity distribution 141 obtained by the light receiving unit 122, the light intensity changes significantly at the edge 11 of the substrate 10.

The algorithm for detecting the edge position of the substrate 10 in the example shown in FIG. 2 uses a determination threshold 151 set between the light intensity obtained outside the edge 11 of the substrate 10 and the light intensity obtained inside the substrate 10. This algorithm specifies, as the edge position of the substrate 10, a point 141a where the light intensity matches the determination threshold 151 in the light intensity distribution 141 measured by the measurement device 120. That is, this algorithm specifies, as the edge position of the substrate 10, the point 141a where the light intensity falls below the determination threshold 151 for the first time in the direction from the edge of the substrate 10 toward the center (barycenter) in the light intensity distribution 141 measured by the measurement device 120. In this manner, in the example shown in FIG. 2, the controller 130 can detect (specify) the edge position of the substrate 10 by applying the algorithm using the determination threshold 151 to the light intensity distribution.

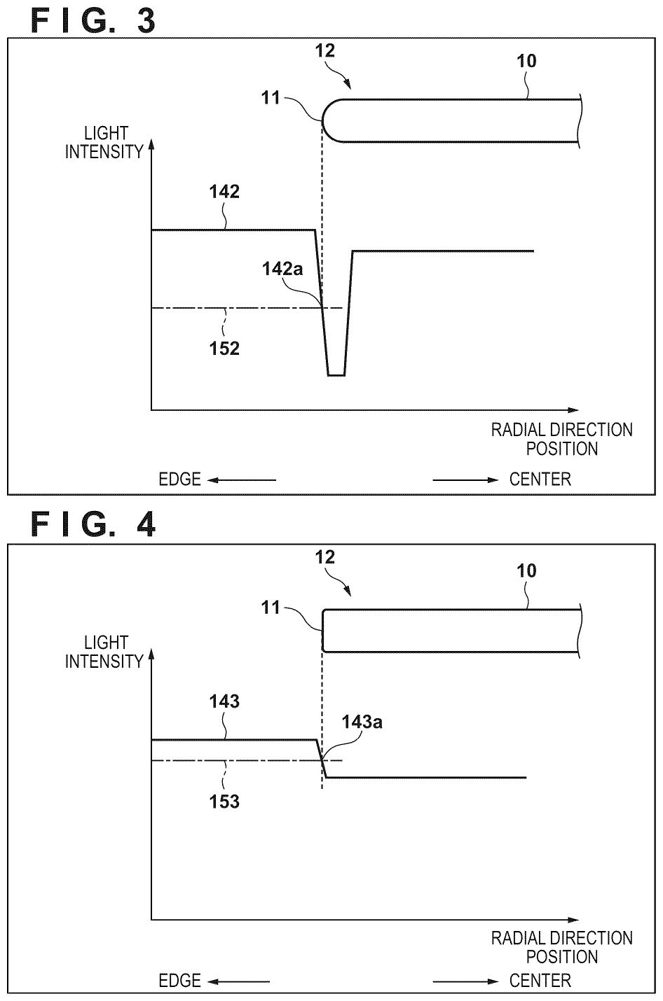

FIG. 3 shows an example where the substrate 10 is a transparent substrate (for example, a glass substrate) and the peripheral edge portion 12 of the substrate 10 is chamfered. In this example, part of the light from the light source unit 121 is reflected by the chamfered peripheral edge portion 12 of the substrate 10 so it does not enter the light receiving unit 122 of the measurement device 120. Therefore, of the light from the light source unit 121, the light having passed outside the edge 11 of the substrate 10 and the light having passed through the portion of the substrate 10 other than the peripheral edge portion 12 enter the light receiving unit 122. Accordingly, as shown in FIG. 3, in a light intensity distribution 142 obtained by the light receiving unit 122, the light intensity in the peripheral edge portion 12 is lower than the light intensity in the other portion.

The algorithm for detecting the edge position of the substrate 10 in the example shown in FIG. 3 uses a determination threshold 152 set between the light intensity obtained outside the edge 11 of the substrate 10 and the light intensity obtained for the peripheral edge portion 12 of the substrate 10. This algorithm specifies, as the edge position of the substrate 10, a point 142a that satisfies a predetermined condition among a plurality of points where the light intensity matches the determination threshold 152 in the light intensity distribution 142 measured by the measurement device 120. The predetermined condition is, for example, a condition that the light intensity matches the determination threshold 152 for the first time in the direction from the edge of the substrate 10 toward the center. That is, this algorithm specifies, as the edge position of the substrate 10, the point 142a where the light intensity falls below the determination threshold 152 for the first time in the direction from the edge of the substrate 10 toward the center in the light intensity distribution 142 measured by the measurement device 120. In this manner, in the example shown in FIG. 3, the controller 130 can detect (specify) the edge position of the substrate 10 by applying the algorithm using the determination threshold 152 and the predetermined condition to the light intensity distribution.

FIG. 4 shows an example where the substrate 10 is a transparent substrate (for example, a glass substrate) and the peripheral edge portion 12 of the substrate 10 is not chamfered. In this example, part of the light from the light source unit 121 passes through the substrate 10, and at that time, the light intensity of the part of the light is decreased (that is, dimmed). Accordingly, as shown in FIG. 4, in a light intensity distribution 143 obtained by the light receiving unit 122 of the measurement device 120, the light intensity changes at the edge 11 of the substrate 10 as a boundary. However, in this example, since the substrate 10 passes light, the change amount of the light intensity in the light intensity distribution 143 is smaller than the change amount of the light intensity in the light intensity distribution 141 shown in FIG. 2.

The algorithm for detecting the edge position of the substrate 10 in the example shown in FIG. 4 uses a determination threshold 153 set between the light intensity obtained outside the edge 11 of the substrate 10 and the light intensity obtained inside the edge 11 of the substrate 10. This algorithm specifies, as the edge position of the substrate 10, a point 143a where the light intensity matches the determination threshold 153 in the light intensity distribution 143 measured by the measurement device 120. That is, this algorithm specifies, as the edge position of the substrate 10, the point 143a where the light intensity falls below the determination threshold 153 for the first time in the direction from the edge of the substrate 10 toward the center in the light intensity distribution 143 measured by the measurement device 120. In this manner, in the example shown in FIG. 4, the controller 130 can detect (specify) the edge position of the substrate 10 by applying the algorithm using the determination threshold 153 to the light intensity distribution.

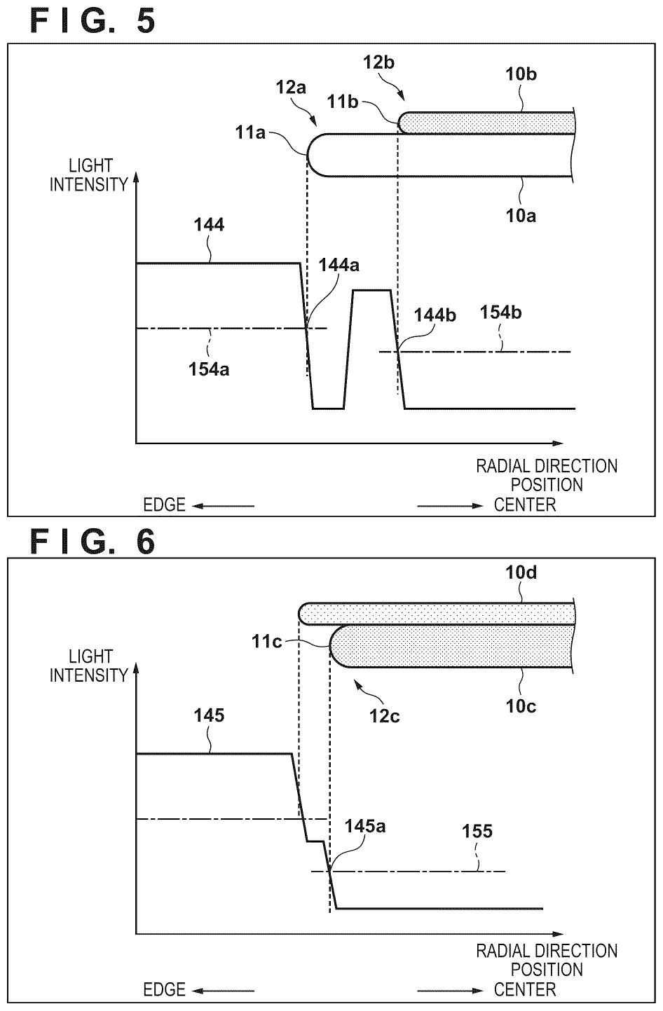

FIG. 5 shows an example where the substrate 10 is a bonded substrate formed from a transparent support substrate 10a (for example, a glass substrate) and an opaque substrate 10b (for example, a silicon substrate) bonded onto the support substrate 10a. The outer shape of the support substrate 10a is larger than the outer shape of the opaque substrate 10b. Each of a peripheral edge portion 12a of the support substrate 10a and a peripheral edge portion 12b of the opaque substrate 10b is chamfered. In this example, part of the light from the light source unit 121 is reflected by the chamfered peripheral edge portion 12a of the support substrate 10a. Therefore, the light passes outside an edge 11a of the support substrate 10a and the portion of the support substrate 10a other than the peripheral edge portion 12a. Further, part of the light having passed through the portion of the support substrate 10a other than the peripheral edge portion 12a is blocked by the opaque substrate 10b. Accordingly, a light intensity distribution 144 obtained by the light receiving unit 122 of the measurement device 120 has the shape shown in FIG. 5.

The algorithm for detecting the edge position of the support substrate 10a in the example shown in FIG. 5 uses a determination threshold 154a set between the light intensity obtained outside the edge 11a of the support substrate 10a and the light intensity obtained for the peripheral edge portion 12a of the support substrate 10a. This algorithm specifies, as the edge position of the support substrate 10a, a point 144a that satisfies a predetermined condition among a plurality of points where the light intensity matches the determination threshold 154a in the light intensity distribution 144 measured by the measurement device 120. The predetermined condition is, for example, a condition that the light intensity matches the determination threshold 154a for the first time in the direction from the edge of the substrate 10 toward the center. That is, this algorithm specifies, as the edge position of the substrate 10, the point 144a where the light intensity falls below the determination threshold 154a for the first time in the direction from the edge of the substrate 10 toward the center in the light intensity distribution 144 measured by the measurement device 120. In this manner, in the example shown in FIG. 5, the controller 130 can detect (specify) the edge position of the support substrate 10a by applying the algorithm using the determination threshold 154a and the predetermined condition to the light intensity distribution.

The algorithm for detecting the edge position of the opaque substrate 10b in the example shown in FIG. 5 uses a determination threshold 154b set between the light intensity obtained outside an edge 11b of the opaque substrate 10b and the light intensity obtained inside the opaque substrate 10b. This algorithm specifies, as the edge position of the opaque substrate 10b, a point 144b that satisfies a predetermined condition among a plurality of points where the light intensity matches the determination threshold 154b in the light intensity distribution 144 measured by the measurement device 120. The predetermined condition is, for example, a condition that the light intensity matches the determination threshold 154b for the third time in the direction from the edge of the substrate 10 toward the center. That is, this algorithm specifies, as the edge position of the substrate 10, the point 144b where the light intensity falls below the determination threshold 154b for the second time in the direction from the edge of the substrate 10 toward the center in the light intensity distribution 144 measured by the measurement device 120. In this manner, in the example shown in FIG. 5, the controller 130 can detect (specify) the edge position of the opaque substrate 10b by applying the algorithm using the determination threshold 154b and the predetermined condition to the light intensity distribution.

FIG. 6 shows an example where the substrate 10 is a substrate formed from an opaque substrate 10c (for example, a glass substrate) and a transparent film 10d bonded onto the opaque substrate 10c. The outer shape of the transparent film 10d is larger than the opaque substrate 10c. A peripheral edge portion 12c of the opaque substrate 10c is chamfered. In this example, part of the light from the light source unit 121 is blocked by the opaque substrate 10c. Further, part of the light having passed outside an edge 11c of the opaque substrate 10c passes through the transparent film 10d, and at that time, the light intensity of the part of the light is decreased (that is, dimmed). Accordingly, a light intensity distribution 145 obtained by the light receiving unit 122 of the measurement device 120 has the shape as shown in FIG. 6.

The algorithm for detecting the edge position of the opaque substrate 10c in the example shown in FIG. 6 uses a determination threshold 155. The determination threshold 155 is set between the light intensity obtained outside the edge 11c of the opaque substrate 10c and inside the transparent film 10d and the light intensity obtained inside the opaque substrate 10c. This algorithm specifies, as the edge position of the opaque substrate 10c, a point 145a where the light intensity of the light intensity distribution measured by the measurement device 120 matches the determination threshold 155 in the light intensity distribution 145 measured by the measurement device 120. That is, this algorithm specifies, as the edge position of the substrate 10, the point 145a where the light intensity falls below the determination threshold 155 for the first time in the direction from the edge of the substrate 10 toward the center in the light intensity distribution 145 measured by the measurement device 120. In this manner, in the example shown in FIG. 6, the controller 130 can detect (specify) the edge position of the opaque substrate 10c by applying the algorithm using the determination threshold 155 to the light intensity distribution.

As has been described above, the light intensity distribution measured by the measurement device 120 (light receiving unit 122) changes in accordance with the material and transparency (transparent/opaque) of the substrate 10, whether the peripheral edge portion 12 is chamfered, and whether the substrate undergoes bonding. That is, if the type of the substrate 10 changes, the tendency of the light intensity distribution measured by the measurement device 120 can change. Hence, in order to accurately detect the edge position of the substrate 10 even if the type of the substrate 10 changes, it is necessary to appropriately select, in accordance with the type of substrate, the algorithm for determining the position of the substrate from the light intensity distribution. However, performing processing of measuring the light intensity distribution by the measurement device 120 while rotationally driving the substrate 10 a plurality of times by changing the type of algorithm to select the algorithm can be disadvantageous in terms of throughput. That is, prealignment processing is demanded to achieve both the throughput and detection accuracy when detecting the position of the substrate 10. Therefore, in this embodiment, a plurality of types of algorithms are applied to one light intensity distribution measured by the measurement device 120 to specify a plurality of candidates for the edge position of the substrate 10 from the light intensity distribution. Then, based on the plurality of specified candidates, one algorithm used to determine the position of the substrate 10 is selected from the plurality of types of algorithms. Note that the candidate for the edge position of the substrate 10 may be referred to as the “edge position candidate” hereinafter.

Here, the plurality of types of algorithms can include at least two types of algorithms different from each other in the determination threshold for specifying the edge position of the substrate 10 from the light intensity distribution. For example, the algorithms used in the examples shown in FIGS. 2 to 6 described above can be different from each other in the determination thresholds 151 to 155 Further, the plurality of types of algorithms can include at least two types of algorithms different from each other in the predetermined condition for, if there are a plurality of points where the light intensity matches the determination threshold in the light intensity distribution, selecting one point from the plurality of points. For example, the algorithms used in the examples shown in FIGS. 3 and 5 can be different from each other in the predetermined condition (more specifically, the condition regarding the number of times the light intensity matches the determination threshold in the direction from the edge of the substrate 10 toward the center).

### [Selection of Algorithm]

The algorithm can be selected by, for example, obtaining an evaluation value for each of the plurality of edge position candidates. The evaluation value for each of the plurality of edge position candidates can be obtained based on at least one of the similarity between the outer shape of the substrate 10 obtained from the edge position and the first reference shape, and the circularity of the outer shape of the substrate 10 obtained from the edge position. Additionally or alternatively, the evaluation value may be obtained based on the similarity between the shape of the cutout portion of the substrate 10 obtained from the edge position and the second reference shape.

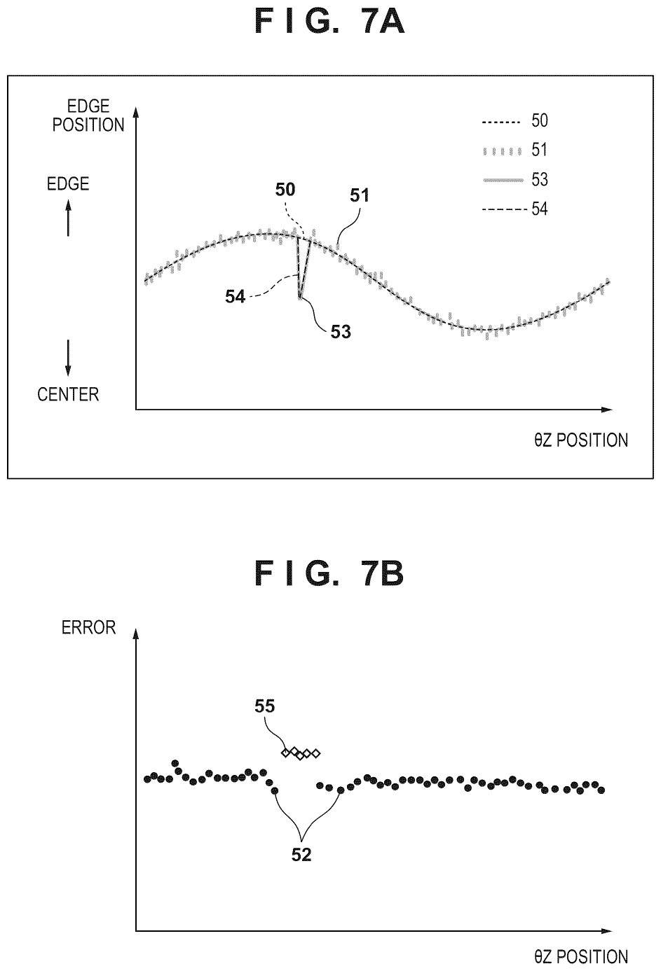

By causing the measurement device 120 to sequentially measure the light intensity distribution in the radial direction while rotationally driving the substrate 10 by the substrate holder 110, the controller 130 can obtain a position waveform 51 indicating the relationship between the position in the θZ direction (circumferential direction) and the edge position as shown in FIG. 7A. In FIG. 7A, the abscissa represents the θZ-direction position of the peripheral edge portion 12 (that is, a rotation angle θ of the substrate 10) where the light intensity distribution is measured by the measurement device 120, and the ordinate represents the edge position in the radial direction specified from the light intensity distribution measured by the measurement device 120. The position waveform 51 may be understood to represent the outer shape of the substrate 10 obtained from the detection result of the edge position. The position waveform 51 includes a partial waveform 53 corresponding to the cutout portion of the substrate 10. The example shown in FIG. 7A shows a case where the cutout portion of the substrate 10 is a notch.

For example, the controller 130 can obtain the evaluation value based on at least one of the similarity between the position waveform 51 representing the outer shape of the substrate 10 and an ideal position waveform 50 representing the ideal outer shape of the substrate 10, and the circularity of the outer shape of the substrate 10 obtained from the position waveform 51. The similarity between the position waveform 51 and the ideal position waveform 50 can be calculated based on errors 52 between the position waveform 51 and the ideal position waveform 50 shown in FIG. 7B. The ideal position waveform 50 is a waveform representing the ideal outer shape of the substrate 10, and may be understood to represent a reference shape (first reference shape) for the outer shape of the substrate 10. The controller 130 can obtain, based on the position waveform 51, the eccentricity (X, Y) and rotation angle θ of the substrate 10 with respect to a center of rotation 125 of the substrate 10 by the substrate holder 110, thereby obtaining the ideal position waveform 50 using following equation (1).

$$f ( θ ) = r cos ( θ + α ) + \sqrt{{L}^{2} - \{ r sin {( θ + α )}^{2} \}} \qquad ( 1 )$$

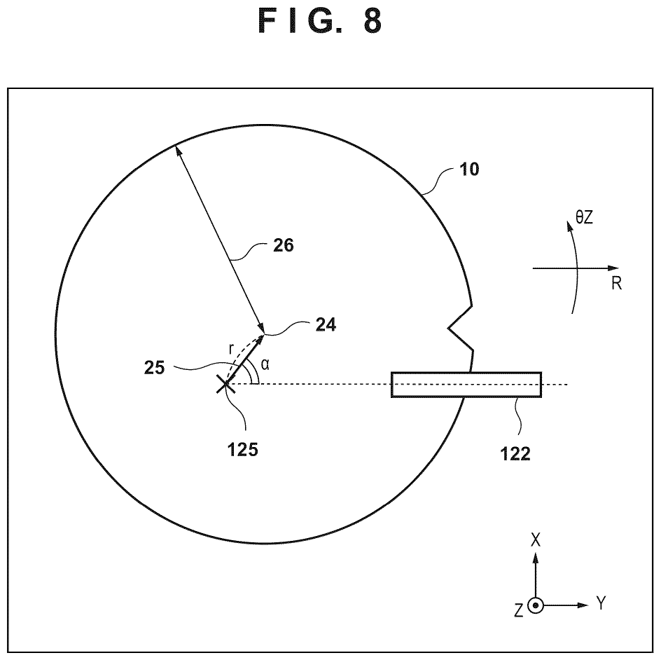

Here, equation (1) will be described with reference to FIG. 8. In FIG. 8, the θZ direction indicates the circumferential direction of the substrate 10, and the R direction indicates the radial direction of the substrate 10. As shown in FIG. 8, when a barycenter 24 (center) of the substrate 10 is eccentric with respect to the center of rotation 125 of the substrate 10 by the substrate holder 110, “r” represents the magnitude of an eccentricity vector 25 (the distance between the center of rotation 125 and the barycenter 24 of the substrate 10). “θ” represents the rotation angle of the substrate 10 by the substrate holder 110. The rotation angle θ may be understood to represent the θZ-direction position of the peripheral edge portion 12 where the light intensity distribution is measured by the measurement device 120. Defining a straight line connecting the center of rotation 125 and the light receiving unit 122 (light receiving element 122a), “α” represents the angle formed by the straight line and the eccentricity vector 25. “L” represents a radius 26 of the substrate 10.

Alternatively, as shown in FIG. 7A, the controller 130 may obtain the evaluation value based on the similarity between the partial waveform 53 representing the shape of the cutout portion of the substrate 10 and the ideal partial waveform 54 representing the ideal outer shape of the cutout portion. The similarity between the partial waveform 53 and the ideal partial waveform 54 can be calculated based on errors 55 between the partial waveform 53 and the ideal partial waveform 54 shown in FIG. 7B. The ideal partial waveform 54 may be understood to represent a reference shape (second reference shape) for the outer shape of the cutout portion of the substrate 10, and can be obtained from the design information (design data or standard information) of the cutout portion of the substrate 10.

### [Operation Sequence of Prealignment Processing]

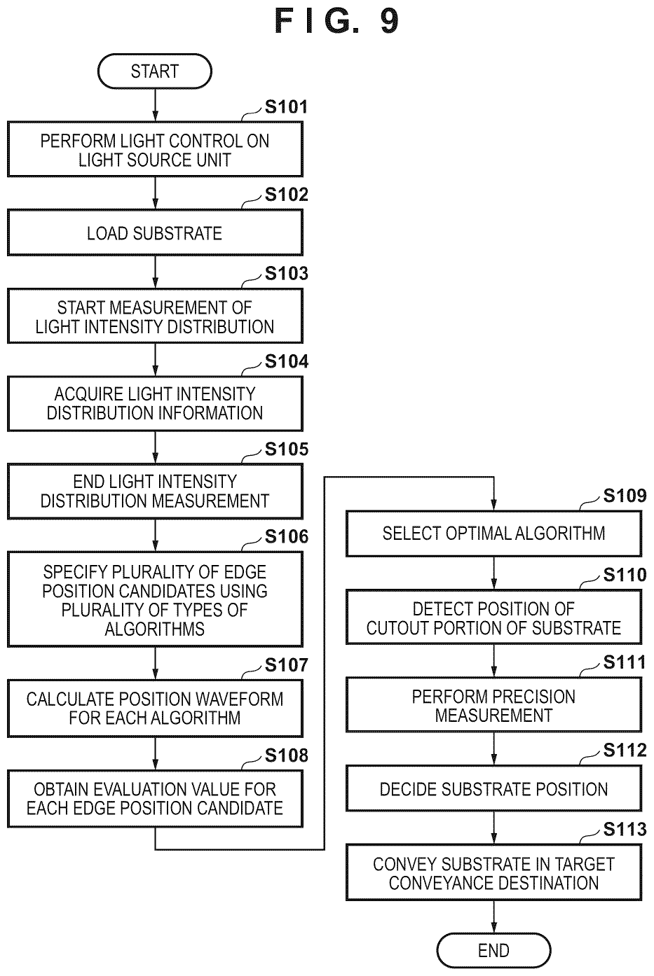

Next, the operation sequence of prealignment processing of this embodiment will be described. FIG. 9 is a flowchart illustrating the operation sequence of prealignment processing of this embodiment. The flowchart of FIG. 9 can be executed by the controller 130.

In step S101, the controller 130 controls the light of the light source unit 121 in the measurement device 120 before loading the substrate 10 onto the substrate holder 110 of the substrate processing apparatus 100. Light control of the light source unit 121 is preferably performed in a state in which the substrate 10 as a light shielding object does not exist in the optical path. If light control of the light source unit 121 is performed after the substrate 10 is loaded onto the substrate holder 110, the light amount cannot be checked in the portion shielded by the substrate 10. As a result, the signal intensity may exceed an allowable value during a rotational operation of the substrate 10.

In step S102, the controller 130 loads the substrate 10 onto the substrate holder 110 of the substrate processing apparatus 100 by a substrate conveyance mechanism (substrate conveyance robot) (not shown). The substrate 10 loaded onto the substrate holder 110 is held by the substrate chuck 111. At the stage when the substrate 10 is loaded onto the substrate holder 110, positioning of the substrate 10 is not performed, and the substrate 10 deviates from the desired position on the substrate holder 110 in the translation direction and the rotation direction.

Steps S103 to S105 constitute a step (first measurement step) of measuring the light intensity distribution by the measurement device 120. In step S103, the controller 130 starts to rotationally drive the substrate 10 in the θZ direction by the substrate holder 110 (rotation driver 112), and also starts to measure the light intensity distribution in the peripheral edge portion 12 of the substrate 10 by the measurement device 120. In step S104, the controller 130 sequentially acquires, from the measurement device 120, information (data) of the light intensity distribution measured by the measurement device 120, and stores it in the storage unit 132. Then, in step S105, after the substrate 10 is rotated by the rotation amount (for example, 360°) required to determine the position of the substrate 10, the controller 130 ends the rotational driving of the substrate 10 by the substrate holder 110 and the measurement of the light intensity distribution by the measurement device 120. The measurement of the light intensity distribution is performed while the substrate 10 is rotationally driven in the θZ direction by the substrate holder 110 (rotation driver 112). That is, the measurement device 120 sequentially (continuously) measures the light intensity distribution in the radial direction in a part of the peripheral edge portion 12 of the substrate 10 while the substrate 10 is rotationally driven by the substrate holder 110. With this, the controller 130 can obtain the light intensity distribution in the radial direction for the whole peripheral edge portion 12 of the substrate 10.

In step S106, the controller 130 applies each of a plurality of types of algorithms to the light intensity distribution acquired through steps S103 to S105 to specify a plurality of edge position candidates from the light intensity distribution (specification step). The plurality of types of algorithms are set to specify the edge position in accordance with the type of the substrate 10, and stored in the storage unit 132. The controller 130 reads out the plurality of algorithms from the storage unit 132, and applies each of the plurality of types of algorithms to one light intensity distribution. Thus, the controller 130 can specify a plurality of edge position candidates from one light intensity distribution. For each light intensity distribution sequentially acquired through steps S103 to S105, a plurality of edge position candidates are specified using the plurality of types of algorithms as described above.

Here, as has been described above, the plurality of types of algorithms can include at least two types of algorithms different from each other in the determination threshold for specifying the edge position of the substrate 10 from one light intensity distribution. Further, the plurality of types of algorithms can include at least two types of algorithms different from each other in the predetermined condition for, if there are a plurality of points where the light intensity matches the determination threshold in one light intensity distribution, selecting one point from the plurality of points. The predetermined condition can include a condition regarding the number of times the light intensity matches the determination threshold in the direction from the edge of the substrate 10 toward the center in the light intensity distribution. For example, the predetermined condition may be a condition that the point where the number of times the light intensity falls below the determination threshold in the direction from the edge of the substrate 10 toward the center in the light intensity distribution reaches a predetermined number of times is specified as the edge position of the substrate 10. Alternatively, the predetermined condition may be a condition that the point where the number of pixels of the light receiving element 122a in each of which the light intensity continuously falls below the determination threshold in the light intensity distribution reaches a predetermined number is specified as the edge position of the substrate 10.

As a specific example, the plurality of types of algorithms can include the algorithm that specifies, as the edge position of the substrate 10, the point 141a where the light intensity falls below the determination threshold 151 for the first time in the direction from the edge of the substrate 10 toward the center in the light intensity distribution 141, as in the example shown in FIG. 2. The plurality of types of algorithms can include the algorithm that specifies, as the edge position of the substrate 10, the point 142a where the light intensity falls below the determination threshold 152 for the first time in the direction from the edge of the substrate 10 toward the center in the light intensity distribution 142, as in the example shown in FIG. 3. The plurality of types of algorithms can include the algorithm that specifies, as the edge position of the substrate 10, the point 143a where the light intensity falls below the determination threshold 153 for the first time in the direction from the edge of the substrate 10 toward the center in the light intensity distribution 143, as in the example shown in FIG. 4.

Further, the plurality of types of algorithms can include the algorithm that specifies, as the edge position of the substrate 10, the point 144a where the light intensity falls below the determination threshold 154a for the first time in the direction from the edge of the substrate 10 toward the center in the light intensity distribution 144, as in the example shown in FIG. 5. The plurality of types of algorithms can include the algorithm that specifies, as the edge position of the substrate 10, the point 144b where the light intensity falls below the determination threshold 154b for the second time in the direction from the edge of the substrate 10 toward the center in the light intensity distribution 144, as in the example shown in FIG. 5. The plurality of types of algorithms can include the algorithm that specifies, as the edge position of the substrate 10, the point 145a where the light intensity falls below the determination threshold 155 for the first time in the direction from the edge of the substrate 10 toward the center in the light intensity distribution 145, as in the example shown in FIG. 6. Note that the determination thresholds 151 to 155 can be values different from each other.

In step S107, the controller 130 calculates the position waveform 51 shown in FIG. 7A for each of the plurality of types of algorithms. As has been described above, the position waveform 51 is a waveform indicating the relationship between the θZ-direction position and the edge position of the substrate 10, and may be understood to represent the outer shape of the substrate 10. The position waveform 51 can include the partial waveform 53 corresponding to the cutout portion of the substrate 10. For example, the controller 130 plots the edge position candidate of the substrate 10 specified for each algorithm in correspondence with the θZ-direction position of the substrate 10. Thus, the controller 130 can calculate the position waveform 51 for each algorithm. In addition, in step S107, the controller 130 can calculate the ideal position waveform 50 as described above.

In step S108, the controller 130 obtains the evaluation value for each of the plurality of edge position candidates (evaluation step). Step S108 may be understood as a step of obtaining the evaluation value for each of the plurality of types of algorithms. In this embodiment, the controller 130 can obtain the evaluation value based on at least one of the similarity between the position waveform 51 and the ideal position waveform 50, the circularity of the outer shape of the substrate 10 obtained from the position waveform 51, and the similarity between the partial waveform 53 and the ideal partial waveform 54. For example, the controller 130 can obtain the evaluation value by calculating the similarity between the position waveform 51 and the ideal position waveform 50 from the total sum value or variance value of the errors 52 between the position waveform 51 and the ideal position waveform 50 shown in FIG. 7B. Alternatively, the controller 130 can obtain the evaluation value by calculating the circularity from the error between a true circle and the outer shape of the substrate 10 obtained from the position waveform 51. The controller 130 may obtain the evaluation value by calculating the similarity between the partial waveform 53 and the ideal partial waveform 54 from the total sum value or variance value of the errors 55 between the partial waveform 53 and the ideal partial waveform 54 shown in FIG. 7B.

Here, the controller 130 may obtain the evaluation value based on a plurality of evaluation indices obtained from the edge position candidate. The plurality of evaluation indices can include at least two of the similarity between the position waveform 51 and the ideal position waveform 50, the circularity of the outer shape of the substrate 10 obtained from the position waveform 51, and the similarity between the partial waveform 53 and the ideal partial waveform 54. In this case, the controller 130 may weight each of the plurality of evaluation indices, and obtain the evaluation value based on the weighting result. For example, the controller 130 can obtain the total sum of the plurality of weighted evaluation indices as the evaluation value.

In step S109, based on the evaluation value obtained for each edge position candidate in step S108, the controller 130 selects, from the plurality of algorithms, one algorithm used to determine the position of the substrate 10 as an optimal algorithm (selection step). For example, the controller 130 can select the edge position candidate with the best evaluation value among the plurality of edge position candidates, and select the algorithm used to specify the selected edge position candidate as the optimal algorithm. As a specific example, in a case of obtaining the total sum value of the errors 52 between the position waveform 51 and the ideal position waveform 50 as the evaluation value, the controller 130 can select, as the optimal algorithm, the algorithm used to specify the edge position candidate with the smallest evaluation value among the plurality of edge position candidates. On the other hand, in a case of obtaining the reciprocal of the total sum value of the errors 52 between the position waveform 51 and the ideal position waveform 50 as the evaluation value, the controller 130 can select, as the optimal algorithm, the algorithm used to specify the edge position candidate with the largest evaluation value among the plurality of edge position candidates.

Steps S110 to S113 constitute a step of controlling positioning of the substrate 10 by using the optimal algorithm selected in step S109. Positioning of the substrate 10 in this embodiment can include positioning of the substrate 10 held by the substrate holder 110, and positioning of the substrate 10 when conveying the substrate 10 from the substrate holder 110 to a target conveyance destination. An example of the target conveyance destination is on the substrate stage of the lithography apparatus.

In step S110, based on the edge position candidate specified by the optimal algorithm, the controller 130 detects the position of the peripheral edge portion 12 (for example, cutout portion) of the substrate 10 held by the substrate holder 110. Then, in step S111, the controller 130 performs precision measurement of remeasuring the light intensity distribution in the peripheral edge portion 12 of the substrate 10 by the measurement device 120 (second measurement step). In the precision measurement, the controller 130 first positions, based on the position of the peripheral edge portion 12 (cutout portion) of the substrate 10 detected in step S110, the substrate 10 such that the peripheral edge portion 12 (cutout portion) of the substrate 10 is arranged in the optical path of the measurement device 120. The positioning of the substrate 10 may be performed by translationally and rotationally driving the substrate 10 by the substrate holder 110, or may be performed by replacing the substrate 10 on the substrate holder 110 by the substrate conveyance mechanism (substrate conveyance robot) (not shown). Then, the controller 130 sequentially measures the light intensity distribution in the peripheral edge portion 12 of the substrate 10 by the measurement device 120 while rotationally driving the substrate 10 by the substrate holder 110. In this embodiment, the controller 130 can precisely measure the light intensity distribution in the cutout portion in the peripheral edge portion 12 of the substrate 10. By performing the precise measurement as described above, it is possible to decrease degradation of processing accuracy caused by the positional deviation of the substrate 10 in the succeeding substrate conveyance operation and processing operation.

In step S112, the controller 130 determines the position of the substrate 10 (decision step). More specifically, the controller 130 specifies the edge position of the substrate 10 by applying the optimal algorithm to the light intensity distribution acquired in step S111. Then, the controller 130 calculates the position waveform 51 from the specified edge position of the substrate 10, and determines the position of the substrate 10 based on the position waveform 51. The position of the substrate 10 determined in step S112 can include at least one of the outer shape of a local region including the cutout portion in the peripheral edge portion 12 of the substrate 10, the edge position of the substrate 10, and the barycenter position of the substrate 10.

In step S113, the controller 130 conveys the substrate 10 from the substrate holder 110 to the target conveyance destination by the substrate conveyance mechanism (substrate conveyance robot) (not shown). At this time, the controller 130 can control, based on the position of the substrate 10 determined in step S112, positioning of the substrate 10 upon conveying the substrate 10 from the substrate holder 110 to the target conveyance destination. For example, the controller 130 can calculate the eccentric amount regarding the positions X, Y, and θZ of the substrate 10 with respect to the substrate holder 110 based on the position of the substrate 10 determined in step S112, and control positioning of the substrate 10 based on the eccentric amount. The positioning of the substrate 10 can be controlled such that the substrate 10 is set at the predetermined position and orientation.

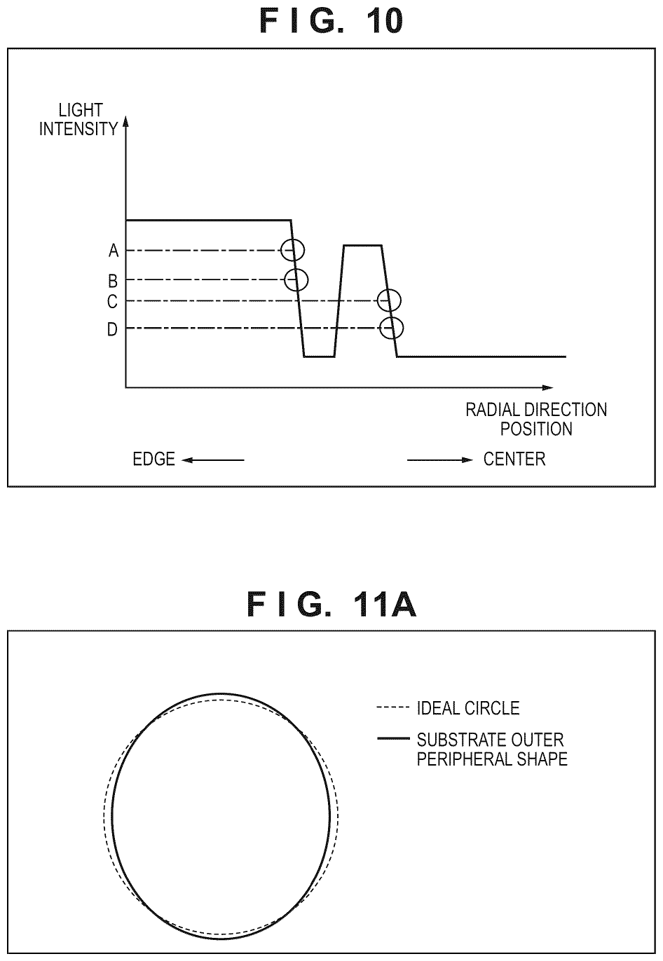

Here, steps S106 to S109 described above will be described in more detail with reference to FIGS. 10 to 12. In step S106, the controller 130 applies a plurality of types of algorithms A to D to one light intensity distribution to specify the edge position candidate for each algorithm, as shown in FIG. 10. In step S107, the controller 130 calculates the position waveform 51 and the ideal position waveform 50 for each algorithm based on the edge position candidate specified for each algorithm in step S106.

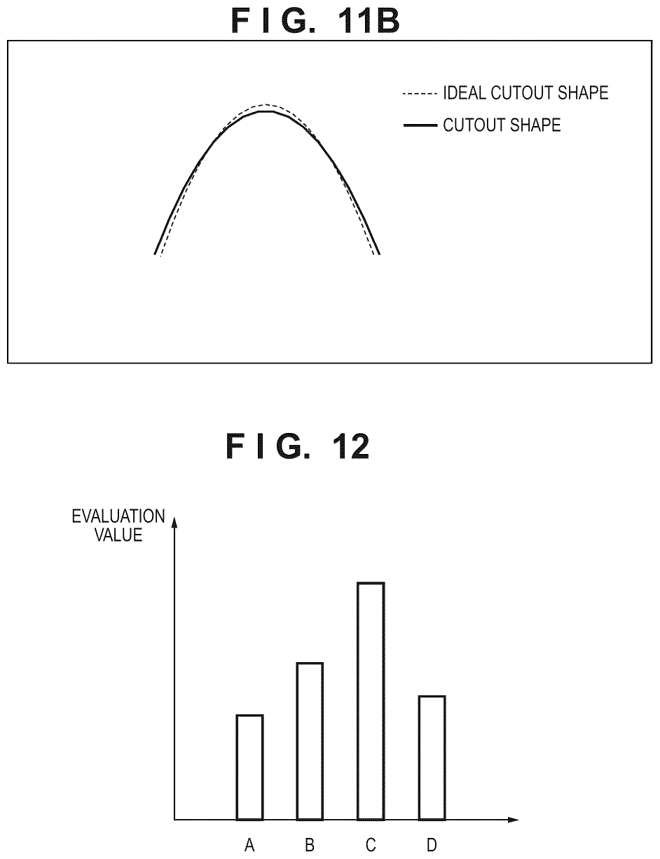

In step S108, as shown in FIG. 11A, the controller 130 calculates the outer shape of the substrate 10 as the substrate outer peripheral shape from the position waveform 51, and calculates the ideal circle (first reference shape) from the ideal position waveform 50. With this, the controller 130 can obtain the evaluation value based on the similarity between the position waveform 51 and the ideal position waveform 50 obtained from the difference between the substrate outer peripheral shape and the ideal circle and/or the circularity of the substrate outer peripheral shape. Further, as shown in FIG. 11B, the controller 130 calculates the outer shape (to be sometimes referred to as the cutout shape hereinafter) of the cutout portion of the substrate 10 from the partial waveform 53, and calculates the ideal cutout shape (second reference shape) of the substrate 10 from the ideal partial waveform 54. With this, the controller 130 can obtain the evaluation value based on the similarity between the partial waveform 53 and the ideal partial waveform 54 obtained from the difference between the cutout shape and the ideal cutout shape. The evaluation value is obtained for each algorithm. FIG. 12 schematically shows the evaluation value obtained for each of the plurality of types of algorithms A to D. In step S109, based on the evaluation value obtained for each of the algorithms A to D, the controller 130 can select, as the optimal algorithm, one algorithm (the algorithm C in FIG. 12) with the best evaluation value from the plurality of types of algorithms A to D.

In step S108, weighting processing may be performed on the plurality of evaluation indices used to calculate the evaluation value. For the weighting processing in step S108, an example of applying two types of algorithms to the light intensity distribution 144 shown in FIG. 5 will be described below. The two types of algorithms include the first algorithm for detecting the edge position (first edge position) of the support substrate 10a and the second algorithm for detecting the edge position (second edge position) of the opaque substrate 10b.

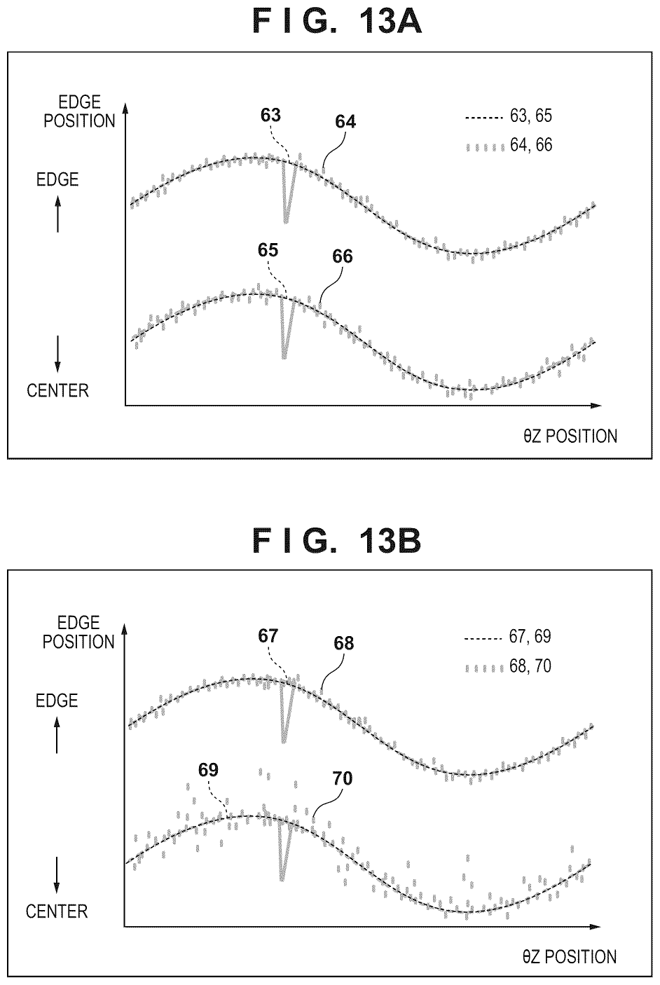

In steps S106 and S107, the controller 130 uses the first algorithm and specifies the point 144a in the light intensity distribution 144 as the edge position (first edge position) of the support substrate 10a. With this, a position waveform 64 of the first edge position and an ideal position waveform 63 can be obtained as shown in FIG. 13A. Similarly, the controller 130 uses the second algorithm and specifies the point 144b in the light intensity distribution 144 as the edge position (second edge position) of the opaque substrate 10b. With this, a position waveform 66 of the second edge position and an ideal position waveform 65 can be obtained as shown in FIG. 13A.

Then, in step S108, when calculating the evaluation value from each position waveform, the controller 130 performs predetermined weighting processing on at least one of the evaluation value of the first edge position and the evaluation value of the second edge position. Here, the predetermined weighting processing can be performed based on the evaluation value of the first edge position obtained from the difference between the position waveform 64 and the ideal position waveform 63 and the evaluation value of the second edge position obtained from the difference between the position waveform 66 and the ideal position waveform 65.

For example, FIG. 13A shows an example where the evaluation value obtained from the position waveform 64 of the first edge position and the ideal position waveform 63 and the evaluation value obtained from the position waveform 66 of the second edge position and the ideal position waveform 65 are comparable. In this example, the predetermined weighting processing is performed to make the evaluation value of the second edge position superior to the evaluation value of the first edge position. It may be understood that when the evaluation value of the first edge position and the evaluation value of the second edge position are comparable, the difference between the evaluation value of the first edge position and the evaluation value of the second edge position is smaller than a threshold.

On the other hand, FIG. 13B shows an example where the evaluation value obtained from a position waveform 68 of the first edge position and an ideal position waveform 67 is sufficiently superior to the evaluation value obtained from a position waveform 70 of the second edge position and an ideal position waveform 69. In this example, the predetermined weighting processing is performed so as not to influence the order of superiority of the evaluation value of the first edge position and the evaluation value of the second edge position.

That is, in step S109, based on the weighting processing, if the evaluation value of the first edge position and the evaluation value of the second edge position are comparable, the second algorithm for detecting the second edge position is selected as the optimal algorithm. On the other hand, if the evaluation value of the first edge position is sufficiently superior to the evaluation value of the second edge position, the first algorithm for detecting the first edge position is selected as the optimal algorithm.

As has been described above, the substrate processing apparatus 100 of this embodiment applies a plurality of types of algorithms to one light intensity distribution measured by the measurement device 120 to specify a plurality of edge position candidates from the one light intensity distribution. Then, based on the plurality of edge position candidates, one algorithm used to determine the position of the substrate 10 is selected as the optimal algorithm from the plurality of types of algorithms. According to this embodiment, it is possible to appropriately select the optimal algorithm using one light intensity distribution without performing processing of measuring the light intensity distribution by the measurement device 120 while rotationally driving the substrate 10 a plurality of times by changing the type of algorithm. That is, it is possible achieve both the throughput and detection accuracy when detecting the position of the substrate 10.

### Second Embodiment

The second embodiment according to the present invention will be described. This embodiment basically takes over the first embodiment, and matters not mentioned below can follow the first embodiment.

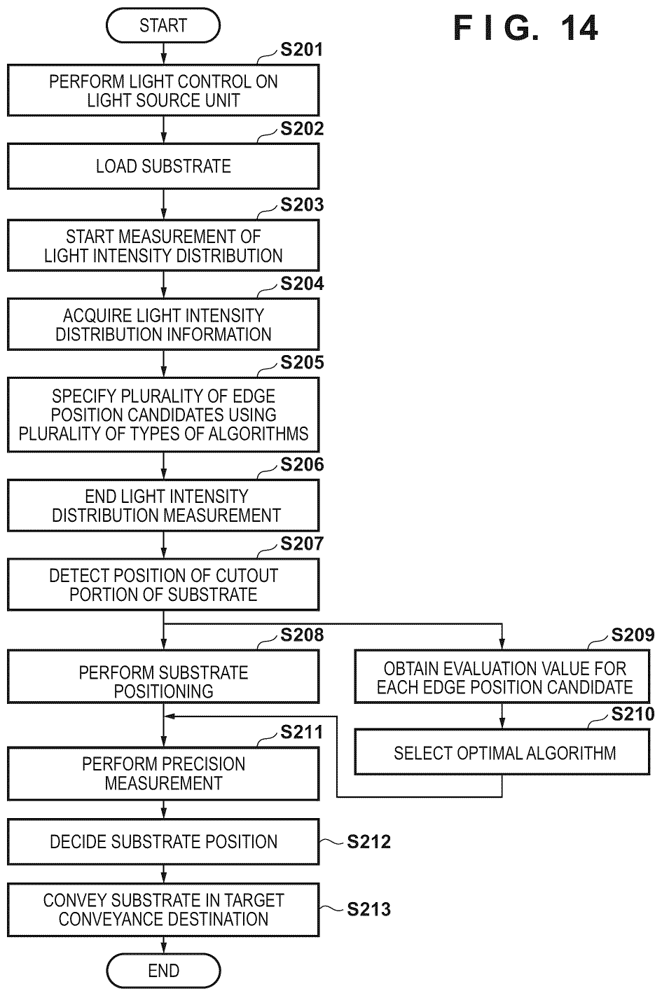

FIG. 14 is a flowchart illustrating the operation sequence of prealignment processing of this embodiment. The flowchart of FIG. 14 can be executed by a controller 130. Note that steps S201 to S204 of the flowchart of FIG. 14 are similar to steps S101 to S104 of the flowchart of FIG. 9, so that a detailed description will be omitted here.

In step S205, the controller 130 applies each of a plurality of types of algorithms to the light intensity distribution sequentially acquired from a measurement device 120 in step S204 to specify a plurality of edge position candidates from the light intensity distribution. At this time, the controller 130 stores the plurality of specified edge position candidates in a storage unit 132. In this manner, each time the light intensity distribution is acquired from the measurement device 120 in step S204, the controller 130 of this embodiment applies each of the plurality of types of algorithms to the light intensity distribution to specify the plurality of edge position candidates. That is, in this embodiment, measurement of the light intensity distribution in step S204 and specifying a plurality of edge position candidates in step S205 are performed in parallel. Note that since step S205 is similar to step S106 of the flowchart of FIG. 9, a detailed description will be omitted here.

In step S206, after a substrate 10 is rotated by the rotation amount (for example, 360°) required to determine the position of the substrate 10, the controller 130 ends the rotational driving of the substrate 10 by a substrate holder 110 and the measurement of the light intensity distribution by the measurement device 120. Note that since step S206 is similar to step S105 of the flowchart of FIG. 9, a detailed description will be omitted here.

In step S207, the controller 130 detects the position of a peripheral edge portion 12 (for example, cutout portion) of the substrate 10 held by the substrate holder 110. The detection of the position of the peripheral edge portion 12 in step S207 may be performed based on the edge position candidate obtained by the algorithm designated in advance, or may be performed based on the edge position candidate obtained by the algorithm used in the previous decision step. The algorithm used in the previous decision step can be the algorithm used for the previous lot or the algorithm used for the previous substrate.

In step S208, based on the position of the peripheral edge portion 12 (cutout portion) of the substrate 10 detected in step S207, the controller 130 positions the substrate 10 such that the peripheral edge portion 12 (cutout portion) of the substrate 10 is arranged in the optical path of the measurement device 120. The positioning of the substrate 10 may be performed by translationally and rotationally driving the substrate 10 by the substrate holder 110, or may be performed by replacing the substrate 10 on the substrate holder 110 by a substrate conveyance mechanism (substrate conveyance robot) (not shown).

Steps S209 and S210 are performed in parallel with step S208. In step S209, the controller 130 obtains the evaluation value for each of the plurality of edge position candidates. Then, in step S210, based on the evaluation value obtained for each edge position candidate in step S209, the controller 130 selects, as the optimal algorithm, one algorithm used to determine the position of the substrate 10 from the plurality of algorithms. Note that since steps S209 and S210 are similar to steps S108 and S109 of the flowchart of FIG. 9, respectively, a detailed description will be omitted here.

In step S211, the controller 130 performs precision measurement of remeasuring the light intensity distribution in the peripheral edge portion 12 of the substrate 10 by the measurement device 120. In precision measurement of this embodiment, since positioning of the substrate 10 has already been performed in step S208, only a step of sequentially measuring the light intensity distribution in the peripheral edge portion 12 of the substrate 10 by the measurement device 120 while rotationally driving the substrate 10 by the substrate holder 110 can be performed. Note that since step S211 is similar to step S111 of the flowchart of FIG. 9, a detailed description will be omitted here.

In step S212, the controller 130 determines the position of the substrate 10. More specifically, the controller 130 specifies the edge position of the substrate 10 by applying the optimal algorithm to the light intensity distribution acquired in step S211. Then, in step S213, the controller 130 conveys the substrate 10 from the substrate holder 110 to the target conveyance destination by the substrate conveyance mechanism (substrate conveyance robot) (not shown). Note that since steps S212 and S213 are similar to steps S112 and S113 of the flowchart of FIG. 9, a detailed description will be omitted here.

As has been described above, in this embodiment, calculation of the evaluation value is performed in parallel with control of positioning of the substrate 10. With this, the throughput of a substrate processing apparatus 100 can be further improved.

### Third Embodiment

The third embodiment according to the present invention will be described. This embodiment basically takes over the first embodiment, and matters not mentioned below can follow the first embodiment. The second embodiment may be applied to this embodiment.

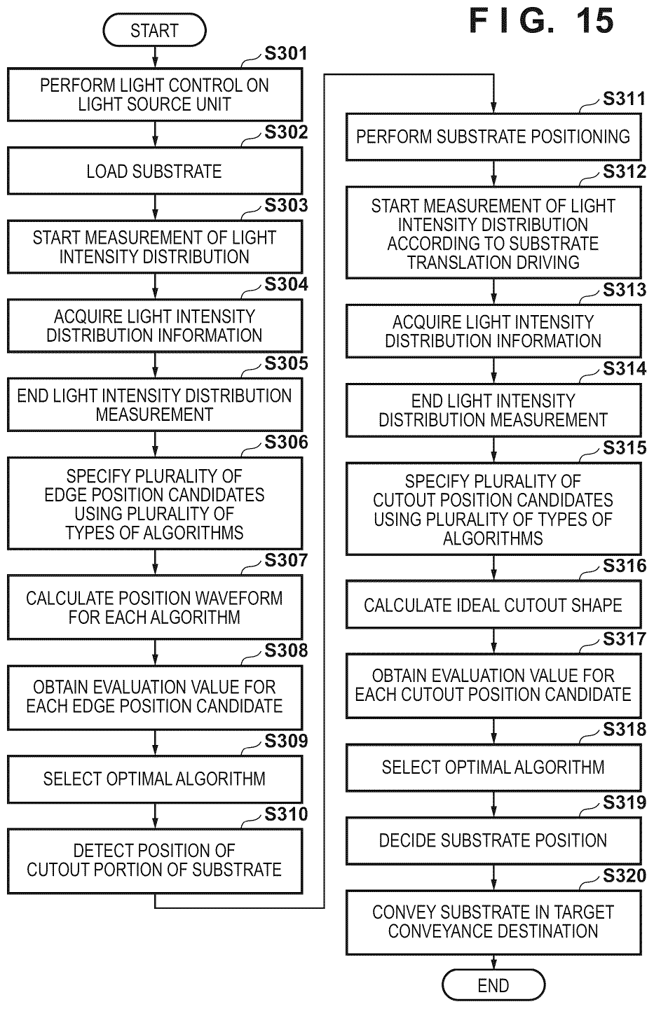

FIG. 15 is a flowchart illustrating the operation sequence of prealignment processing of this embodiment. The flowchart of FIG. 15 can be executed by a controller 130. Note that steps S301 to S310 of the flowchart of FIG. 15 are similar to steps S101 to S110 of the flowchart of FIG. 9, so that a detailed description will be omitted here.

In step S311, based on the position of a peripheral edge portion 12 (cutout portion) of a substrate 10 detected in step S310, the controller 130 positions the substrate 10 such that the peripheral edge portion 12 (cutout portion) of the substrate 10 is arranged in the optical path of a measurement device 120. The positioning of the substrate 10 may be performed by translationally and rotationally driving the substrate 10 by a substrate holder 110, or may be performed by replacing the substrate 10 on the substrate holder 110 by a substrate conveyance mechanism (substrate conveyance robot) (not shown).

In step S312, the controller 130 starts translation driving of the substrate 10 in the X direction by the substrate holder 110 (translation driver 113), and starts measurement of the light intensity distribution by the measurement device 120. For example, during the translation driving of the substrate 10 in the X direction by the substrate holder 110, a light receiving unit 122 (light receiving element 122a) of the measurement device 120 receives the light from a light source unit 121, thereby continuously acquiring, in the X direction, the light intensity distribution in the peripheral edge portion 12 of the substrate 10 including a cutout portion. That is, in step S312, the light intensity distribution in the cutout portion of the substrate 10 is measured by translationally driving the cutout portion of the substrate 10 in the X direction with respect to the optical path of the measurement device 120.

In step S313, the controller 130 sequentially acquires, from the measurement device 120, information (data) of the light intensity distribution measured by the measurement device 120 and stores it in a storage unit 132. After the substrate 10 is translationally driven by the amount required to determine the position of the substrate 10, the controller 130 ends the translation driving of the substrate 10 and the measurement of the light intensity distribution by the measurement device 120 in step S314.

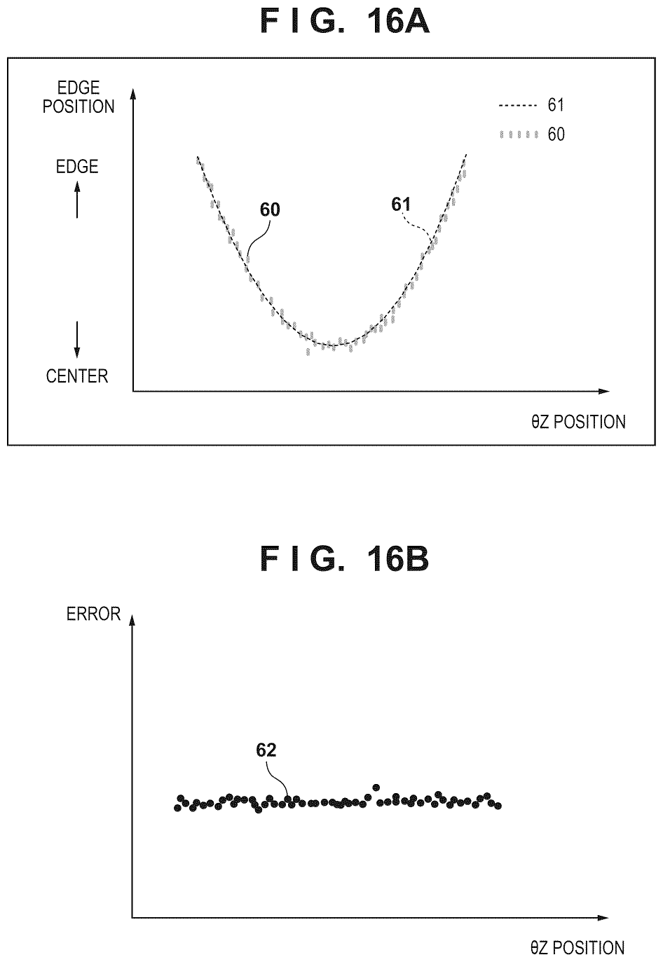

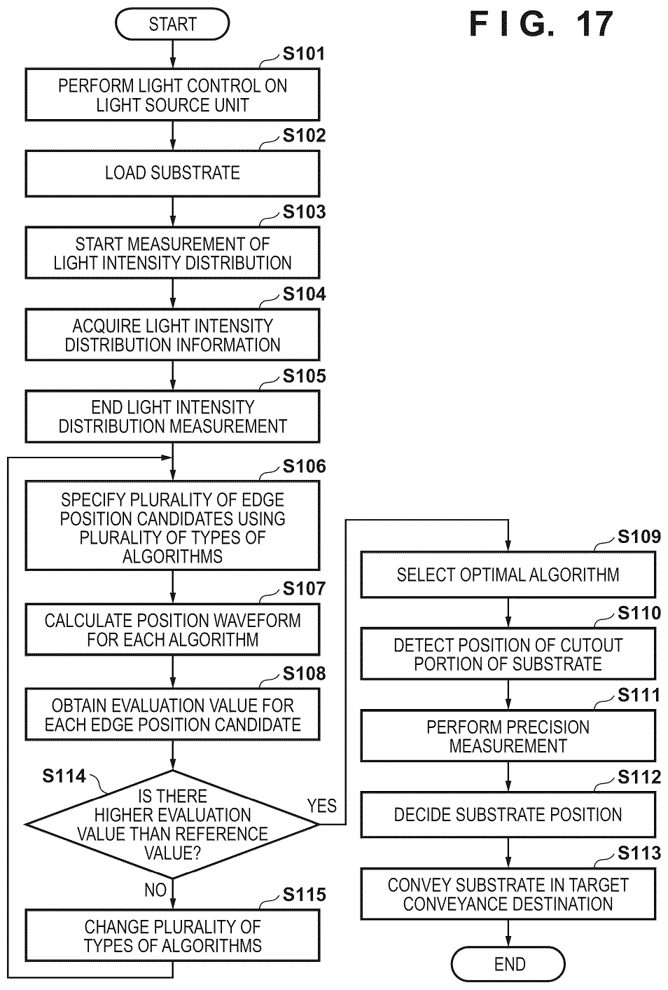

In step S315, the controller 130 applies each of a plurality of types of algorithms to the light intensity distribution sequentially acquired through steps S312 and S313, thereby specifying a plurality of candidates (cutout position candidates) for the position of the cutout portion of the substrate 10. With this, the controller 130 can obtain a cutout waveform 60 as shown in FIG. 16A for each algorithm. The cutout waveform 60 is a waveform corresponding to the cutout portion of the substrate 10. In FIG. 16A, the abscissa represents the θZ-direction position of the peripheral edge portion 12 (that is, a rotation angle θ of the substrate 10) where the light intensity distribution is measured by the measurement device 120, and the ordinate represents the edge position in the radial direction specified from the light intensity distribution measured by the measurement device 120.

In step S316, the controller 130 calculates an ideal cutout waveform 61 by performing curve approximation using a least squares method on the cutout waveform 60. The ideal cutout waveform 61 may be understood to represent the ideal outer shape of the cutout portion of the substrate 10. Note that in this embodiment, the cutout portion of the substrate 10 is expressed as a notch, but the cutout portion of the substrate 10 may be an orientation flat. In a case where the cutout portion of the substrate 10 is an orientation flat, the controller 130 calculates the ideal cutout waveform by performing linear approximation using a least squares method on the waveform corresponding to the cutout portion of the substrate 10.

In step S317, the controller 130 obtains the evaluation value for each of the plurality of cutout position candidates. For example, the controller 130 obtains errors 62 between the cutout waveform 60 and the ideal cutout waveform 61 as shown in FIG. 16B, and obtains the evaluation value based on the errors 62. For example, the controller 130 can obtain the evaluation value based on the total sum value or variance value of the errors 62. The evaluation value can be obtained for each algorithm. Here, if steps S312 to S316 are performed a plurality of times, the evaluation value may be based on the average value of the total sum values of the errors 62 obtained over the plurality of times.

In step S318, the controller 130 compares the evaluation values obtained for the respective algorithms obtained in step S317, and selects the algorithm with the best evaluation value as the optimal algorithm. The optimal algorithm selected in step S318 may be the same as or different from the optimal algorithm selected in step S309.

In step S319, the controller 130 determines the position of the substrate 10 using the optimal algorithm selected in step S318. More specifically, the controller 130 applies the optimal algorithm to the light intensity distribution acquired through steps S312 to S314, thereby specifying the edge position of the substrate 10. Then, the controller 130 calculates the position waveform from the specified edge position of the substrate 10, and determines the position of the substrate 10 based on the position waveform.

In step S320, the controller 130 conveys the substrate 10 from the substrate holder 110 to the target conveyance destination by a substrate conveyance mechanism (substrate conveyance robot) (not shown). At this time, the controller 130 can control, based on the position of the substrate 10 determined in step S319, positioning of the substrate 10 upon conveying the substrate 10 from the substrate holder 110 to the target conveyance destination. Note that since step S320 is similar to step S113 of the flowchart of FIG. 9, a detailed description will be omitted here.

According to this embodiment, as in the first embodiment, it is possible to achieve both the throughput and detection accuracy when detecting the position of the substrate 10.

### Fourth Embodiment

The fourth embodiment according to the present invention will be described. This embodiment basically takes over the first embodiment, and matters not mentioned below can follow the first embodiment. The second embodiment and/or the third embodiment may be applied to this embodiment.

FIG. 17 is a flowchart illustrating the operation sequence of prealignment processing of this embodiment. The flowchart of FIG. 17 can be executed by a controller 130. Note that the flowchart of FIG. 17 is the same as the flowchart of FIG. 9 except that steps S114 to S115 are added. Therefore, steps S114 and S115 will be described below, and a detailed description of other steps S101 to S113 will be omitted.

Step S114 is inserted between step S108 and step S109. In step S114, the controller 130 compares evaluation values respectively obtained for a plurality of edge position candidates in step S108 with a reference value to determine whether there is an edge position candidate with the evaluation value higher than the reference value. The reference value is set in advance to the evaluation value calculated from the position waveform obtained in a case where the position of the cutout portion of the substrate 10 cannot be detected or the barycentric position of the substrate 10 cannot be detected. If there is an edge position candidate with the evaluation value higher than the reference value, the process advances to step S109. If there is no edge position candidate with the evaluation value higher than the reference value, the process advances to step S115. In step S115, the controller 130 changes a plurality of types of algorithms applied to the light intensity distribution sequentially acquired through steps S103 to S105. Then, after changing the plurality of types of algorithms, the controller 130 performs steps S106 to S108. Here, the light intensity distribution to which the plurality of types of algorithms after the change are applied is the same as the light intensity distribution to which the plurality of types of algorithms before the change are applied. The plurality of types of algorithms after the change may be different from the plurality of types of algorithms before the change in a determination threshold or a predetermined condition.

In this embodiment, regarding the algorithm selected as the optimal algorithm in the prealignment processing executed in the past, it is possible to apply the algorithm selected frequently and the algorithm selected infrequently separately to the light intensity distribution. More specifically, in step S106 for the first time, the algorithms selected frequently used in the past prealignment processing can be applied to the light intensity distribution. On the other hand, if all the evaluation values obtained by the algorithms selected frequently fall below the reference value, the algorithms selected infrequently can be applied to the light intensity distribution in step S106 for the second time.

As has been described above, in this embodiment, the algorithms can be changed (switched) to calculate evaluation values and select the algorithm. That is, fewer algorithms (algorithms selected frequently as the optimal algorithm) than in the first embodiment are applied in steps S106 to S108 for the first time. Therefore, the time required for calculation processing using algorithms can be shortened, and the throughput can be improved as compared to the first embodiment.

Note that the embodiments described above are merely examples. The present invention is not limited to the above-described arrangements and shapes, and modifications and changes are possible, as appropriate, within the range of the present invention. For example, there may be two or more measurement devices 120 (sensors), and different algorithms may be applied to the plurality of measurement devices 120.

### <Embodiment of Lithography Apparatus>

An embodiment of a lithography apparatus according to the present invention will be described. A lithography apparatus is an apparatus that is employed for a lithography process as a manufacturing process for a semiconductor device or liquid crystal display device and forms a pattern on a substrate. As a lithography apparatus, there is available an exposure apparatus that transfers a pattern of an original onto a substrate by exposing the substrate to light through the original. The following will exemplify an exposure apparatus as a lithography apparatus.

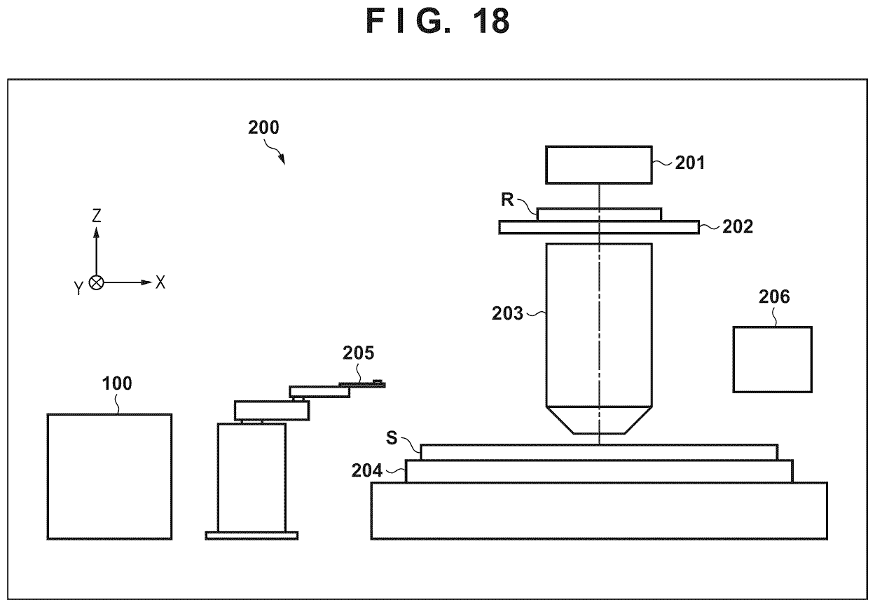

FIG. 18 is a schematic view showing an example of the arrangement of an exposure apparatus 200. The exposure apparatus 200 transfers the pattern on an original R onto a substrate S by, for example, a step-and-repeat scheme or step-and-scan scheme. As shown in FIG. 18, the exposure apparatus 200 can include an illumination optical system 201, an original stage 202, a projection optical system 203, a substrate stage 204, a conveyance apparatus 205, and a controller 206. In the exposure apparatus 200, the illumination optical system 201, the original stage 202, the projection optical system 203, and the substrate stage 204 function as forming units that form a pattern on the substrate S.

The exposure apparatus 200 includes the above-described substrate processing apparatus 100 that processes the substrate S. The substrate processing apparatus 100 performs prealignment processing of the substrate S as processing of the substrate S. Then, the substrate S processed by the substrate processing apparatus 100 is conveyed onto the substrate stage 204 by the conveyance apparatus 205. For example, based on the position of the substrate S determined by the prealignment processing of the substrate S, a controller 130 of the substrate processing apparatus 100 controls positioning of the substrate S when conveying the substrate S onto the substrate stage 204 by the conveyance apparatus 205. Note that the controller 206 of the exposure apparatus 200 and the controller 130 of the substrate processing apparatus 100 may be formed integrally or separately.

### <Embodiment of Article Manufacturing Method>

The lithography apparatus as described above can be used to perform an article manufacturing method for manufacturing various articles (for example, a semiconductor IC device, a liquid crystal display device, and MEMS). An article manufacturing method according to an embodiment of the present invention is suitable for manufacturing, for example, an article such as a device (a semiconductor device, a magnetic storage medium, or a liquid crystal display device). This article manufacturing method includes a processing step of processing a substrate by the above-described substrate processing method (substrate processing apparatus), a formation step of forming a pattern on the substrate having undergone the processing step, and a manufacturing step of manufacturing an article from the substrate having undergone the formation step. The processing step may be understood as a step of performing prealignment processing as processing of the substrate. This article manufacturing method can further include other known steps (oxidation, deposition, vapor deposition, doping, planarization, etching, resist removal, dicing, bonding, packaging, and the like). The article manufacturing method according to this embodiment is advantageous in at least one of the performance, the quality, the productivity, and the production cost of the article, as compared with a conventional method.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-182051 filed on Oct. 23, 2023, which is hereby incorporated by reference herein in its entirety.

What is claimed is:

1. A substrate processing method of processing a substrate, comprising:
measuring a light intensity distribution obtained from a peripheral edge portion of the substrate when the peripheral edge portion is illuminated with light from a light source unit;
specifying a plurality of candidates for an edge position of the substrate from the light intensity distribution measured in the measuring, by applying each of a plurality of types of algorithms to the light intensity distribution; and
selecting one algorithm used to determine a position of the substrate from the plurality of types of algorithms based on the plurality of candidates specified in the specifying.

2. The method according to claim 1, wherein
each of the plurality of types of algorithms is set to specify the edge position based on a point where a light intensity matches a determination threshold in the light intensity distribution, and
the plurality of types of algorithms include at least two types of algorithms different from each other in the determination threshold.

3. The method according to claim 1, wherein
each of the plurality of types of algorithms is set to specify the edge position based on, if there are a plurality of points where a light intensity matches a determination threshold in the light intensity distribution, a point that satisfies a predetermined condition among the plurality of points, and
the plurality of types of algorithms include at least two types of algorithms different from each other in the predetermined condition.

4. The method according to claim 1, further comprising
obtaining an evaluation value for each of the plurality of candidates specified in the specifying,
wherein in the selecting, one algorithm is selected from the plurality of types of algorithms based on the evaluation value obtained for each of the plurality of candidates obtained in the obtaining.

5. The method according to claim 4, wherein
in the obtaining, the evaluation value is obtained for each of the plurality of candidates based on a similarity between an outer shape of the substrate obtained from the edge position and a first reference shape.

6. The method according to claim 4, wherein
in the obtaining, the evaluation value is obtained for each of the plurality of candidates based on a circularity of an outer shape of the substrate obtained from the edge position.

7. The method according to claim 4, wherein
in the obtaining, the evaluation value is obtained for each of the plurality of candidates based on a similarity between a shape of a cutout portion of the substrate obtained from the edge position and a second reference shape.

8. The method according to claim 4, wherein
in the obtaining, the evaluation value is obtained for each of the plurality of candidates specified in the specifying, based on a plurality of evaluation indices obtained from the edge position, and
the plurality of evaluation indices include at least two of a similarity between an outer shape of the substrate obtained from the edge position and a first reference shape, a circularity of an outer shape of the substrate obtained from the edge position, and a similarity between a shape of a cutout portion of the substrate obtained from the edge position and a second reference shape.

9. The method according to claim 8, wherein
in the obtaining, the evaluation value is obtained based on a result of applying a predetermined weighting to each of the plurality of evaluation indices.

10. The method according to claim 4, further comprising:
remeasuring, after positioning the substrate such that the peripheral edge portion of the substrate is arranged in an optical path of light from the light source unit, a light intensity distribution obtained from the peripheral edge portion; and
determining a position of the substrate by applying the one algorithm selected in the selecting to the light intensity distribution measured in the remeasuring,
wherein the obtaining is performed in parallel with positioning of the substrate in the remeasuring.

11. The method according to claim 10, wherein
positioning of the substrate in the remeasuring is performed based on a candidate of the edge position specified in the specified using one of an algorithm designated in advance and an algorithm used in the previous deciding among the plurality of types of algorithms.

12. The method according to claim 1, wherein
the measuring and the specifying are performed in parallel.

13. An article manufacturing method comprising:
processing a substrate by using a substrate processing method according to claim 1;
forming a pattern on the substrate having undergone the processing; and
manufacturing an article from the substrate having undergone the forming.

14. A substrate processing apparatus for processing a substrate, comprising:
a measurement device configured to measure a light intensity distribution obtained from a peripheral edge portion of the substrate when the peripheral edge portion is illuminated with light; and
a controller configured to control positioning of the substrate,
wherein the controller specifies a plurality of candidates for an edge position of the substrate from the light intensity distribution by applying each of a plurality of types of algorithms to the light intensity distribution measured by the measurement device, and selects one algorithm used to determine a position of the substrate from the plurality of types of algorithms based on the plurality of candidates.

15. A lithography apparatus for forming a pattern of a substrate, comprising:
a substrate processing apparatus according to claim 14; and
a formation device configured to form a pattern on the substrate processed by the substrate processing apparatus.

16. A non-transitory computer-readable storage medium storing a program for causing a computer to execute a method comprising:
specifying, based on a result of measuring a light intensity distribution obtained from a peripheral edge portion of the substrate when the peripheral edge portion is illuminated with light, a plurality of candidates for an edge position of the substrate from the light intensity distribution by applying each of a plurality of types of algorithms to the light intensity distribution; and
selecting one algorithm used to determine a position of the substrate from the plurality of types of algorithms based on the plurality of candidates specified in the specifying.
